(19) United States
(12) Patent Application Publication
(10) Pub. No.: US 2026/0026056 A1
(43) Pub. Date: Jan. 22, 2026

(54) STRESSED PFET NANOSHEETS

(71) Applicant: International Business Machines Corporation, Armonk, NY (US)

(72) Inventors: Mohamed Abdelmaksoud Mohamed Rabie, Clifton Park, NY (US); Dureseti Chidambarrao, Weston, CT (US)

(21) Appl. No.: 18/773,742

(22) Filed: Jul. 16, 2024

(51) Int. Cl. H01L 29/06; H01L 29/423; H01L 29/66; H01L 29/775; H01L 29/786

(52) U.S. Cl. CPC H10D 62/121; H10D 30/43; H10D 30/6713; H10D 30/6735; H10D 30/6757; H10D 64/018

(57) ABSTRACT

Semiconductor devices are provided in which at least recessed inner dielectric spacers are used in forming a PFET having stressed semiconductor channel material nanosheets. The use of the recessed inner dielectric spacers facilitates an increase in strain transfer from the source/drain regions of the PFET to the semiconductor channel material nanosheets. Thus, the semiconductor channel material nanosheets of the present application have enhanced stress as compared to equivalent semiconductor channel material nanosheets in which non-recessed inner dielectric spacers are used.

### BACKGROUND

The present application relates to semiconductor technology, and more particularly to semiconductor devices including a p-type field effect transistor (PFET) having stressed semiconductor channel material nanosheets.

The use of non-planar semiconductor devices is the next step in the evolution of complementary metal oxide semiconductor (CMOS) devices. One type of non-planar semiconductor device that has been touted as a viable option beyond the 7 nm technology node is a nanosheet device. By “nanosheet device” it is meant that the device contains one or more layers of semiconductor channel material portions (i.e., semiconductor channel material nanosheets) having a vertical thickness that is substantially less than its width. Unlike transitional planar transistors, nanosheet transistors typically use wider and thicker semiconductor channel material portions that are completely surrounded by a gate structure. As such, nanosheet transistors are often referred to as a gate-all-around (GAA) device. The GAA design reduces avenues for current leakage and boosts the amount of current the device can drive. In GAA devices, the current flows through multiple stacks of semiconductor channel material nanosheets, enhancing performance while maintaining simplicity at their core.

### SUMMARY

Semiconductor devices are provided in which at least recessed inner dielectric spacers are used in forming a PFET having stressed semiconductor channel material nanosheets. The use of the recessed inner dielectric spacers facilitates an increase in strain transfer from the source/drain regions of the PFET to the semiconductor channel material nanosheets. Thus, the semiconductor channel material nanosheets of the present application have enhanced stress as compared to equivalent semiconductor channel material nanosheets in which non-recessed inner dielectric spacers are used.

In one embodiment of the present application, the semiconductor device includes a p-type field effect transistor including a vertical stack of stressed and spaced apart semiconductor channel material nanosheets, a gate structure wrapped around a portion of each semiconductor channel material nanosheet of the vertical stack of stressed and spaced apart semiconductor channel material nanosheets, and a strained source/drain region located on each side of the vertical stack of stressed and spaced apart semiconductor channel material nanosheets. The semiconductor device further includes a recessed inner dielectric spacer located beneath each semiconductor channel material nanosheet of the vertical stack of stressed and spaced apart semiconductor channel material nanosheets. The recessed inner dielectric spacer has an outermost sidewall that is located between a width of each semiconductor channel material nanosheet of the vertical stack of stressed and spaced apart semiconductor channel material nanosheets.

In another embodiment of the present application, the semiconductor device includes a p-type field effect transistor including a vertical stack of stressed and spaced apart semiconductor channel material nanosheets, a gate structure wrapped around a portion of each semiconductor channel material nanosheet of the vertical stack of stressed and spaced apart semiconductor channel material nanosheets, and a strained source/drain region located on each side of the vertical stack of stressed and spaced apart semiconductor channel material nanosheets. The semiconductor device further includes a recessed inner dielectric spacer located beneath each semiconductor channel material nanosheet of the vertical stack of stressed and spaced apart semiconductor channel material nanosheets. The recessed inner dielectric spacer has an outermost sidewall that is located between a width of each semiconductor channel material nanosheet of the vertical stack of stressed and spaced apart semiconductor channel material nanosheets. The semiconductor device even further includes a semiconductor spacer separating the strained source/drain region from each semiconductor channel material nanosheet of the vertical stack of stressed and spaced apart semiconductor channel material nanosheets and from the recessed inner dielectric spacer.

In a further embodiment of the present application, the semiconductor device includes a p-type field effect transistor including a vertical stack of stressed and spaced apart semiconductor channel material nanosheets, a gate structure wrapped around a portion of each semiconductor channel material nanosheet of the vertical stack of stressed and spaced apart semiconductor channel material nanosheets, and a strained source/drain region located on each side of the vertical stack of stressed and spaced apart semiconductor channel material nanosheets. The semiconductor device further includes a recessed inner dielectric spacer located beneath each semiconductor channel material nanosheet of the vertical stack of stressed and spaced apart semiconductor channel material nanosheets. The recessed inner dielectric spacer has an outermost sidewall that is located between a width of each semiconductor channel material nanosheet of the vertical stack of stressed and spaced apart semiconductor channel material nanosheets. The semiconductor device even further includes an inner semiconductor spacer located adjacent to the recessed inner dielectric spacer. The inner semiconductor spacer has an outermost sidewall that is vertically aligned to an end of each semiconductor channel material nanosheet of the vertical stack of stressed and spaced apart semiconductor channel material nanosheets.

### BRIEF DESCRIPTION OF THE DRAWINGS

FIG. 1 is a cross sectional view of an exemplary structure that can be employed in the present application, the exemplary structure including a nanosheet stack of alternating recessed sacrificial semiconductor material nanosheets and semiconductor channel material nanosheets, and an inner dielectric spacer located at each of the ends of the recessed sacrificial semiconductor material nanosheets.

FIG. 2 is a cross sectional view of the exemplary structure of FIG. 1 after recessing each of the inner dielectric spacers.

FIG. 3 is a cross sectional view of the exemplary structure of FIG. 2 after forming strained source/drain regions.

FIG. 4 is a cross sectional view of the exemplary structure of FIG. 3 after replacing the recessed sacrificial semiconductor material nanosheets with a gate structure.

FIG. 5 is a cross sectional view of the exemplary structure of FIG. 2 after forming a semiconductor spacer.

FIG. 6 is a cross sectional view of the exemplary structure of FIG. 5 after forming strained source/drain regions.

FIG. 7 is a cross sectional view of the exemplary structure of FIG. 6 after replacing the recessed sacrificial semiconductor material nanosheets with a gate structure.

FIG. 8 is cross sectional view of the exemplary structure of FIG. 2 after forming an inner semiconductor spacer adjacent to the recessed inner dielectric spacer.

FIG. 9 is a cross sectional view of the exemplary structure of FIG. 8 after forming strained source/drain regions.

FIG. 10 is a cross sectional view of the exemplary structure of FIG. 9 after replacing the recessed sacrificial semiconductor material nanosheets with a gate structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. In the embodiment described in the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology.

Several device performance parameters can be improved by introducing strain to one or more of the materials in the nanosheet transistor architecture. In general, a crystalline material is “strained” when its atoms have been stretched or compressed outside of their normal inter-atomic distances. In current nanosheet PFET fabrication using non-recessed dielectric inner spacers, the source/drain regions are typically strained by using a material with a different lattice spacing like silicon germanium (SiGe). When the semiconductor channel material nanosheets are released by removing the sacrificial semiconductor material nanosheets, compressive strain in the source/drain regions is transferred to the semiconductor channel material nanosheets since the semiconductor channel material nanosheets are not constrained by the sacrificial semiconductor material nanosheets anymore. The goal in current nanosheet PFET fabrication using non-recessed dielectric inner spacers is to have compressive strain in the semiconductor channel material nanosheets to enhance hole mobility in the PFET device. There is a need to increase the amount of strain that is being transferred from the strained source/drain regions into the semiconductor channel material nanosheets. This increased (i.e., enhanced) strain transfer is obtained in the present application by utilizing a recessed inner dielectric spacer instead of a non-recessed inner dielectric spacer.

Referring first to FIG. 1, there is illustrated an exemplary structure that can be employed in the present application. The exemplary structure illustrated in FIG. 1 includes a nanosheet stack located on a substrate which includes at least a semiconductor device layer 10. The nanosheet stack includes alternating recessed sacrificial semiconductor material nanosheets 12 and semiconductor channel material nanosheets 14. The exemplary structure illustrated in FIG. 1 further includes an inner dielectric spacer 16 located at each of the ends (i.e., end wall) of the recessed sacrificial semiconductor material nanosheets 12.

The semiconductor device layer 10 is composed of a first semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. In one example, the semiconductor device layer 10 is composed of silicon.

In some embodiments, and in addition to the semiconductor device layer 10, the substrate can also include a semiconductor base layer and/or an etch stop layer. The semiconductor base layer, which is located beneath the semiconductor device layer 10, is composed of a second semiconductor material which can be compositionally the same as, or compositionally different from the first semiconductor material that provides the semiconductor device layer 10. The etch stop layer, which is located beneath the semiconductor device layer 10, and in some embodiments between the semiconductor base layer and the semiconductor device layer 10, can be composed of a dielectric material such as, for example, silicon dioxide and/or boron nitride. In other embodiments of the present application, the etch stop layer is composed of a third semiconductor material that is compositionally different from the first semiconductor material that provides the semiconductor device layer 10 and the second semiconductor material that provides the semiconductor base layer. The substrate including the semiconductor device layer 10 can be processed to include shallow trench isolation structures (not shown).

As mentioned above, a nanosheet stack of alternating recessed sacrificial semiconductor material nanosheets 12 and semiconductor channel material nanosheets 14 is present on the semiconductor device layer 10. Although the present application illustrates a single nanosheet stack located on the semiconductor device layer 10, the present application works when a plurality of nanosheet stacks are present on the semiconductor device layer 10. Each recessed sacrificial semiconductor material nanosheet 12 of the nanosheet stack is composed of a fourth semiconductor material, while each semiconductor channel material nanosheet 14 of the nanosheet stack is composed of a fifth semiconductor material. In the present application, the fourth semiconductor material that provides each sacrificial semiconductor material nanosheet 12 is compositionally different from the fifth semiconductor material that provides each semiconductor channel material nanosheet 14. This aspect of the present application allows for the selective removal of each recessed sacrificial semiconductor material nanosheet 12 relative to each semiconductor channel material nanosheet 14. In the present application, the fifth semiconductor material that provides each semiconductor channel material nanosheet 14 provides high channel mobility for PFET devices. In one example, each semiconductor channel material nanosheet 14 is composed of silicon, while each recessed sacrificial semiconductor material nanosheet 12 is composed of a SiGe alloy.

The number of recessed sacrificial semiconductor material nanosheets 12 and semiconductor channel material nanosheets 14 that are present in the nanosheet stack can vary so along as each nanosheet stack includes at least two semiconductor channel material nanosheets 14. By way of one example, and as is illustrated in FIG. 1, the nanosheet stack includes three recessed sacrificial semiconductor material nanosheets 12 and three semiconductor channel material nanosheets 14. Each recessed sacrificial semiconductor material nanosheets 12 in the nanosheet stack has a width that is less than a width of each semiconductor channel material nanosheet 14.

Each inner dielectric spacer 16 is composed of a spacer dielectric material such as, for example, SiN, SiBCN, SiOCN or SiOC. Each inner dielectric spacer 16 has a first sidewall in direct physically contact with an end of one of the sacrificial semiconductor material nanosheets 12 and a second sidewall, opposite the first sidewall, which is vertically aligned to an outermost end (i.e., end wall) of each semiconductor channel material nanosheet 14.

The exemplary structure shown in FIG. 1 can be formed utilizing any nanosheet fabrication process known to those skilled in the art. The nanosheet fabrication process can include deposition of a material stack of alternating fourth semiconductor material-containing layers and fifth semiconductor material-containing layers, followed by nanosheet patterning of the material stack utilizing a sacrificial gate structure (not shown) as an etch mask which converts the material stack into a nanosheet stack of alternating sacrificial semiconductor material nanosheets (unetched portions of the fourth semiconductor material-containing layers) and semiconductor channel material nanosheets 14 (unetched portions of the fifth semiconductor material-containing layers). A recess etch is then employed to convert the sacrificial semiconductor material nanosheets into the recessed sacrificial semiconductor material nanosheets 12 illustrated in FIG. 1.

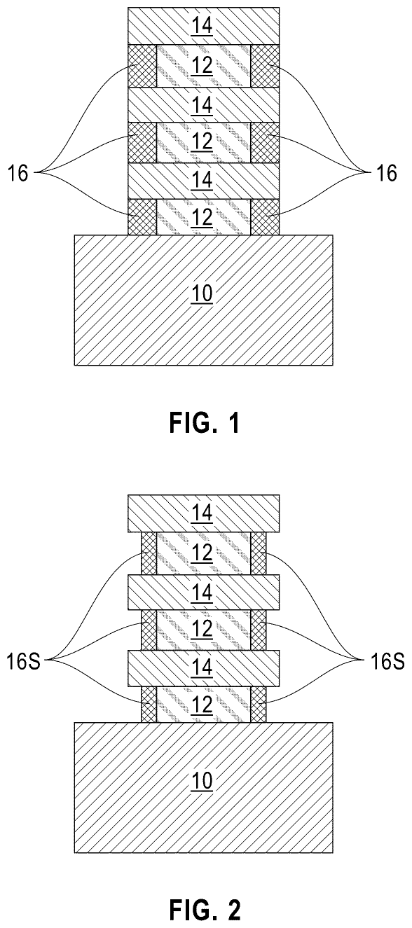

Referring now to FIG. 2, there is illustrated the exemplary structure of FIG. 1 after recessing each of the inner dielectric spacers 16 to provide recessed (or pulled back) inner dielectric spacers 16S. The recessing of the inner dielectric spacers 16 is performed utilizing a lateral etching process that is selective in recessing the inner dielectric spacers 16. The lateral etching process forms a gap next to each of the recessed inner dielectric spacers 16S which is located beneath each semiconductor channel material nanosheet 14 that is present in the nanosheet stack. Each recessed inner dielectric spacer 16S has a width that is less than a width of the original inner dielectric spacers 16. Each recessed inner dielectric spacer 16S is indented in comparison to the original inner dielectric spacers 16. The recessed inner dielectric spacers 16S provide an underhanging region beneath each end portion of semiconductor channel material nanosheets 14. Thus, in the present application, the outermost sidewall of the recessed inner dielectric spacer 16S is vertically offset and does not extend beyond the end of each of the semiconductor channel material nanosheets 14 of the nanosheet stack. Stated in other terms, each recessed inner dielectric spacer 16S has an outermost sidewall that is located between a width of each semiconductor channel material nanosheet 14. It is noted that the width of each of the recessed inner dielectric spacer 16S determines the amount of stress that will be subsequently transferred into each of the each of the semiconductor channel material nanosheets 14 of the nanosheet stack. In the present application, there is an increase in stress upon each of the semiconductor channel material nanosheets 14 of the nanosheet stack as the width of the recessed inner dielectric spacer 16S decreases.

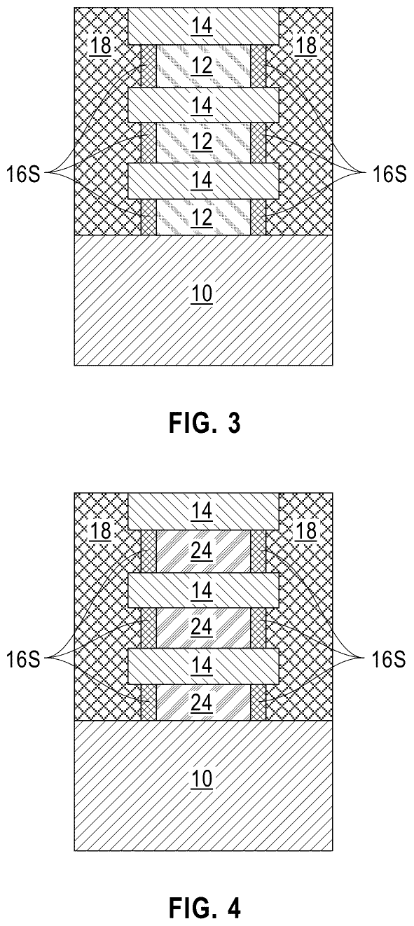

Referring now to FIG. 3, there is illustrated the exemplary structure of FIG. 2 after forming strained source/drain regions 18. Each strained source/drain region 18 is located on opposing sides of a given nanosheet stack. Each strained source/drain region 18 extends outward from an end wall of the semiconductor channel material nanosheets 14 of a given nanosheet stack. In this embodiment, each strained source/drain region 18 fills in the gap that is located adjacent to the recessed inner dielectric spacers 16S. Each strained source/drain region 18 is composed of a sixth semiconductor material and a dopant. As used herein, a “source/drain” region can be a source region or a drain region depending on subsequent wiring and application of voltages during operation of the transistor. The sixth semiconductor material that provides each strained source/drain region 18 is compositionally different from the fifth semiconductor material that provides each semiconductor channel material nanosheet 14. The dopant that is present in the strained source/drain regions 18 is a p-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, gallium and indium. In one example, each strained source/drain region 18 can have a dopant concentration of from 4×10²⁰ atoms/cm³ to 3×10²¹ atoms/cm³. In one example, each strained source/drain region 18 is composed of a SiGe alloy having boron as the doped.

Each strained source/drain region 18 is formed by an epitaxial growth process. In the present application, the terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial growth process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). In some embodiments, the epitaxial growth can be performed at a temperature of from 300° C. to 800° C. The epitaxial growth can be performed utilizing any well-known precursor gas or gas mixture. Carrier gases like hydrogen, nitrogen, helium and argon can be used. In embodiments, the p-typed dopant as defined above is added to the precursor gas or gas mixture.

In conventional nanosheet PFET fabrication without recessed inner dielectric spacers (and assuming that silicon is used for both the semiconductor device layer and the semiconductor channel material nanosheets and SiGe is used as the material for the source/drain regions, and the source/drain regions are formed epitaxy), the SiGe will grow from the bottom (i.e., on the semiconductor device layer) and will have longitudinal stress due to Si to SiGe lattice mismatch but no vertical stress. SiGe will also grow a buffer layer on the exposed sidewalls of Si channels. The SiGe growing there will have vertical stress, but no longitudinal stress. As SiGe continues to grow from both the bottom and sidewalls both growth fronts will merge. The regions touching the Si channels will have minimum longitudinal stress. When the channel is released some of the longitudinal stress will transfer to the channels, but the stress level transferred will be low given the sidewall buffer that grew on the channels. In the present application in which recessed inner dielectric spacers 16S are formed, the SiGe buffer layer will grow horizontally as well as vertically on the sidewall resulting in some longitudinal stress in the semiconductor channel material nanosheets 14. In addition, the buffer layer will grow in all directions slowing the horizontal growth. As a result, the SiGe portion growing from the semiconductor device layer 10 will be larger in volume. This will enhance the longitudinal stress in the stained source/drain regions 18 and as a result will enhance the stress transferred to the semiconductor channel material nanosheets 14. The more recess in the inner spacer region the more stress in the semiconductor channel material nanosheets 14

The presence of the recessed inner dielectric spacers 16S permits the growth of strained source/drain regions 18 that are in compression in a longitudinal direction of current flow. The strained source/drains regions 18 thus provide stress to each of the semiconductor channel material nanosheets 14 as explained above and enhanced stress is achieved utilizing recessed inner dielectric spacer 16S as compared to non-recessed dielectric inner spacers. Typically, non-recessed inner dielectric spacers provide semiconductor channel material nanosheets that have a stress on the order of about 1 GPa; the term “about” when used in the presence of a numerical value denotes that the value can be within ±10% of the recited value. In the present application in which recessed inner dielectric spacers 16S are employed, the semiconductor channel material nanosheets 14 have an enhanced stress (i.e., compressive stress) that is 1.5 to 2 times greater than that of the prior art in which non-recessed inner dielectric spacers are employed. Typically, the stress (compressive stress) in the semiconductor channel material nanosheets 14 of the present application is from about 1.5 GPa to about 2 GPa. In the present application, there is an increase in the percentage of stress on each of the semiconductor channel material nanosheets with a decrease in inner dielectric spacer width. The presence of the recessed inner dielectric spacer 16S also allows for the source/drain regions to be substantially strained which is not typically the situation when non-recessed inner dielectric spacers are present.

After forming the strained source/drain regions 18, an interlayer dielectric (ILD) layer (not shown) is formed. The ILD layer embeds the strained source/drain regions 18 and protects the strained source/drain regions 18 during the subsequent removal of the recessed sacrificial semiconductor material nanosheets 12. The ILD layer is composed of an ILD material such as, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. All dielectric constants mentioned herein are measured in a vacuum unless otherwise noted. ILD layer can be formed by deposition of the ILD material, followed by a planarization process (such as, for example, chemical mechanical polishing (CMP)). The planarization process stops on a surface of the sacrificial gate structure that is present on the nanosheet stack.

Referring now to FIG. 4, there is illustrated the exemplary structure of FIG. 3 after replacing the recessed sacrificial semiconductor material nanosheets 12 with a gate structure 24. Although not shown in the cross view of FIG. 4, the gate structure 24 would be located above the topmost semiconductor channel material nanosheet of the nanosheet stack. The portion of the gate structure 24 that is located above the topmost semiconductor channel material nanosheet would be bounded between a gate spacer (also not shown in the drawings). The replacing of the recessed sacrificial semiconductor material nanosheets 12 includes first revealing the nanosheet stack by removing the sacrificial gate structure that is located on the nanosheet stack. With the nanosheet stack revealed, an etch that is selective in removing recessed sacrificial semiconductor material nanosheets 12 relative to the semiconductor channel material nanosheets 14 is performed. The removal of the recessed sacrificial semiconductor material nanosheets 12 suspends a portion of each of the semiconductor channel material nanosheets 14 of the nanosheet stack. Notably, the removal of the recessed sacrificial semiconductor material nanosheets 12 provides the vertical stack of stressed and spaced apart semiconductor channel material nanosheets 14.

The gate structure 24 is then formed in contact with the suspended portion of each of the semiconductor channel material nanosheets 14. Notably, the gate structure 24 wraps around each semiconductor channel material nanosheet 14 of the nanosheet stack. The gate structure 24 includes a gate dielectric material and a gate electrode, both of which are not separately shown, but intended to be within the region defined by the gate structure. As is known to those skilled in the art, a gate dielectric material directly contacts a physically exposed surface(s) of the semiconductor channel region, and a gate electrode is formed on the gate dielectric material. The gate dielectric material has a dielectric constant of 4.0 or greater. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The gate structure 24 can be formed by deposition, followed by planarization.

Notably, FIG. 4 illustrates a semiconductor device in accordance with an embodiment of the present application. The semiconductor device illustrated in FIG. 4 includes a p-type field effect transistor including a vertical stack of stressed and spaced apart semiconductor channel material nanosheets (i.e., semiconductor channel material nanosheets 14), gate structure 24 wrapped around a portion of each semiconductor channel material nanosheet of the vertical stack of stressed and spaced apart semiconductor channel material nanosheets, and strained source/drain region 18 located on each side of the vertical stack of stressed and spaced apart semiconductor channel material nanosheets. The semiconductor device further includes recessed inner dielectric spacer 16S located beneath each semiconductor channel material nanosheet 14 of the vertical stack of stressed and spaced apart semiconductor channel material nanosheets. The recessed inner dielectric spacer 16S has an outermost sidewall that is located between a width of each semiconductor channel material nanosheet 14 of the vertical stack of stressed and spaced apart semiconductor channel material nanosheets. In the illustrated embodiment, the strained source/drain region 18 is in compression in a longitudinal direction of current flow.

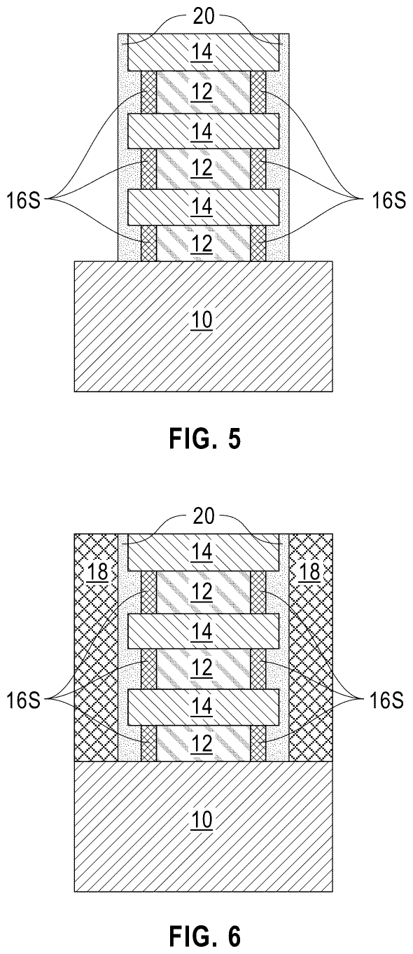

Referring now to FIG. 5, there is illustrated the exemplary structure of FIG. 2 after forming a semiconductor spacer 20. Semiconductor spacer 20 is composed of a seventh semiconductor material which compositionally different from the fourth semiconductor material that provides each recessed sacrificial semiconductor material nanosheet 12. The seventh semiconductor material that provides the semiconductor spacer 20 can be compositionally the same as, or compositionally different from, the fifth semiconductor material that provides each semiconductor channel material nanosheet 14. In one embodiment, the semiconductor spacer 20 and each semiconductor channel material nanosheet 14 are composed of silicon. The semiconductor spacer 20 can be formed by an epitaxial growth process, followed by a spacer etch. The semiconductor spacer 20 fills in the gap that is located next to each of the recessed inner dielectric spacers 16S and is present along an end of each of the semiconductor channel material nanosheets 14 present in the nanosheet stack. The semiconductor spacer 20 has a bottommost surface that is in direct physical contact with the semiconductor device layer 10, and a topmost surface that is substantially coplanar with a topmost surface of the topmost second channel material nanosheet of the nanosheet stack. The semiconductor spacer 20 serves as a semiconductor buffer layer. When the semiconductor spacer 20 is present, it will increase the sidewall surface area and therefore the sixth semiconductor material that provides the strained source/drain regions 18 will grow everywhere on the side wall. This will result in the following advantageous growth: the sixth semiconductor material that provides the strained source/drain regions 18 will grow uniformly and unidirectionally from the side wall. This will slow down the sixth semiconductor material growth rate from the side resulting in the bottom growing taking larger volume. The sixth semiconductor material growing from the semiconductor device layer 10 upwards is more advantageous given the large longitudinal stress it provides to the semiconductor channel material nanosheets 14. In addition, this simultaneous uniform growth from the bottom and from the sidewalls will minimize the number of growth fronts and, consequently, will minimize the defects and stacking faults when the growth fronts merge. This will enhance the stress in the source/drain regions and will enhance the stress transferred to the semiconductor channel material nanosheets 14.

Referring now to FIG. 6, there is illustrated the exemplary structure of FIG. 5 after forming strained source/drain regions 18. The strained source/drain regions 18 of this embodiment are the same as that described above for the embodiment illustrated in FIG. 3 except that strain source/drain regions 18 grow outward from a physically exposed sidewall of the semiconductor spacer 20. The presence of the recessed inner dielectric spacers 16S in this embodiment provides isolation between the strained source/drain regions 18 and the sacrificial gate structure allowing effective release of the semiconductor channel material nanosheets 14 which is required in transferring the stress to each of the semiconductor channel material nanosheets 14. The recessed inner dielectric spacers 16S will allow growth of the buffer layer downwards resulting in a quicker and more uniform formation of the semiconductor spacer 20. The semiconductor spacer 20 will also be thinner compared to the case if non-recessed inner dielectric spacers are employed. Thus, the presence of the inner dielectric spacers 16S in this embodiment ensures that the semiconductor spacer 20 growing has some degree of uniformity. For example and when the semiconductor spacer 20 is composed of Si, epitaxial Si will grow from both the sides and the top and bottom of exposed semiconductor channel material nanosheets 14. Si will fill the recessed gaps and then will start to grow sideways forming this semi-uniform sidewalls. Without the recessed inner dielectric spacer 16S, this Si buffer will likely grow in the form of diamonds which has the issues described above.

Referring now to FIG. 7, there is illustrated the exemplary structure of FIG. 6 after replacing the recessed sacrificial semiconductor material nanosheets 12 with gate structure 24. The replacing step and the gate structure 24 used in this embodiment of the present application are the same as that described above for providing the exemplary structure shown in FIG. 4.

Notably, FIG. 7 illustrates a semiconductor device in accordance with an embodiment of the present application. The semiconductor device illustrated in FIG. 7 includes a p-type field effect transistor including a vertical stack of stressed and spaced apart semiconductor channel material nanosheets (i.e., semiconductor channel material nanosheets 14), gate structure 24 wrapped around a portion of each semiconductor channel material nanosheet of the vertical stack of stressed and spaced apart semiconductor channel material nanosheets, and strained source/drain region 18 located on each side of the vertical stack of stressed and spaced apart semiconductor channel material nanosheets. The semiconductor device further includes recessed inner dielectric spacer 16S located beneath each semiconductor channel material nanosheet 14 of the vertical stack of stressed and spaced apart semiconductor channel material nanosheets. The recessed inner dielectric spacer 16S has an outermost sidewall that is located between a width of each semiconductor channel material nanosheet 14 of the vertical stack of stressed and spaced apart semiconductor channel material nanosheets. The semiconductor device illustrated in FIG. 7 even further includes semiconductor spacer 20 separating the strained source/drain region 18 from each semiconductor channel material nanosheet 14 of the vertical stack of stressed and spaced apart semiconductor channel material nanosheets and from the recessed inner dielectric spacer 16S. In the illustrated embodiment, the strained source/drain region 18 is in compression in a longitudinal direction of current flow.

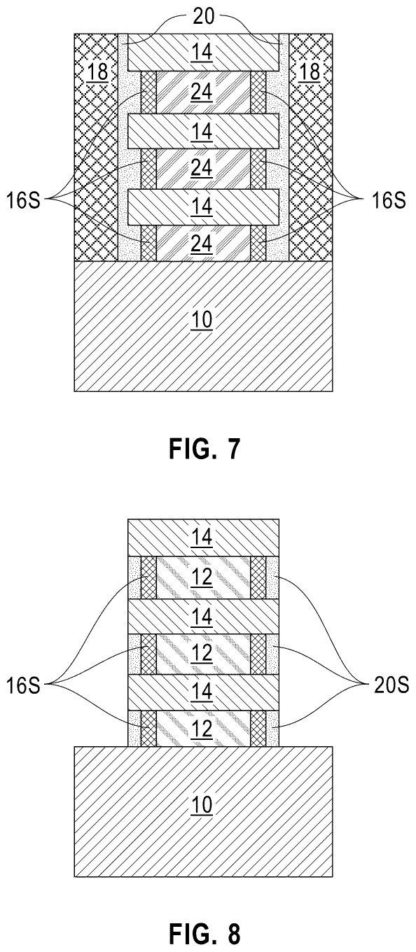

Referring now to FIG. 8, there is illustrated the exemplary structure of FIG. 2 after forming an inner semiconductor spacer 20S adjacent to each recessed inner dielectric spacer 16S. The inner semiconductor spacer 20S are formed by first forming the exemplary structure illustrated in FIG. 5. After forming the illustrated exemplary structure shown in FIG. 5, an anisotropic etch is performed on the semiconductor spacer 20. The anisotropic etch removes the semiconductor spacer 20 from the sidewalls of each semiconductor channel material nanosheet 14 while leaving the semiconductor spacer 20 in the gap that is located adjacent to each recessed inner dielectric spacer 16S. The semiconductor spacer 20 that remains in the gap that is located adjacent to each recessed inner dielectric spacer 16S provides the inner semiconductor spacer 20S illustrated in FIG. 8. Each inner semiconductor spacer 20S has a first sidewall (i.e., innermost sidewall) in direct physical contact with a sidewall of the recessed inner dielectric spacer 16S, and a second sidewall (i.e., outermost sidewall) opposite the first sidewall that is vertical aligned to an end of each semiconductor channel material nanosheet 14. The formation of the inner semiconductor spacer 20S removes any uneven growth surface of the semiconductor spacer 20 and allows for subsequent growth of the strained source/drain regions 18 closer to each semiconductor channel material nanosheet 14 as compared to the exemplary structure including the semiconductor spacer 20.

Referring now to FIG. 9, there is illustrated the exemplary structure of FIG. 8 after forming strained source/drain regions 18. The strained source/drain regions 18 of this embodiment are the same as that described above for the embodiment illustrated in FIG. 3 except that strain source/drain regions 18 grow outward from a physically exposed sidewall of each semiconductor channel material nanosheet 14 and from a physically exposed sidewall of each inner semiconductor spacer 20S. The presence of the inner dielectric spacers 16S in this embodiment provides the enhanced stress transfer from the strained source/drain region 18 into the semiconductor channel material nanosheets 14 as mentioned above. In addition, the presence of the inner dielectric spacers 16S in this embodiment ensures that the inner semiconductor spacers 20S has some degree of uniformity, See comments made above regarding the semiconductor spacer 20. The presence of the inner semiconductor spacers 20S can increase the volume of the strained source/drain regions 18 growing from the bottom and will enhance the uniformity of the sidewall surface resulting in more uniform and unidirectional epitaxial source/drain material growing from the sidewalls.

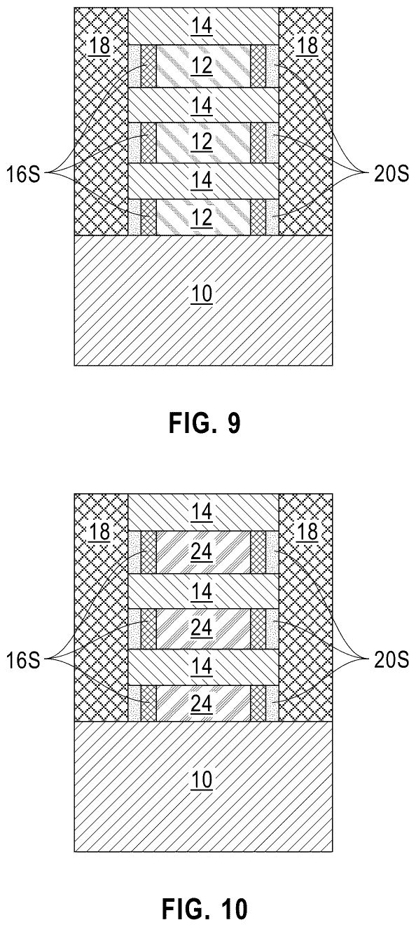

Referring now to FIG. 10, there is illustrated the exemplary structure of FIG. 9 after replacing the recessed sacrificial semiconductor material nanosheets with gate structure 24. The replacing step and the gate structure 24 used in this embodiment of the present application are the same as that described above for providing the exemplary structure shown in FIG. 4. Notably, FIG. 10 illustrates a semiconductor device in accordance with an embodiment of the present application. The semiconductor device illustrated in FIG. 10 includes a p-type field effect transistor including a vertical stack of stressed and spaced apart semiconductor channel material nanosheets (i.e., semiconductor channel material nanosheets 14), gate structure 24 wrapped around a portion of each semiconductor channel material nanosheet of the vertical stack of stressed and spaced apart semiconductor channel material nanosheets, and strained source/drain region 18 located on each side of the vertical stack of stressed and spaced apart semiconductor channel material nanosheets. The semiconductor device further includes recessed inner dielectric spacer 16S located beneath each semiconductor channel material nanosheet 14 of the vertical stack of stressed and spaced apart semiconductor channel material nanosheets. The recessed inner dielectric spacer 16S has an outermost sidewall that is located between a width of each semiconductor channel material nanosheet 14 of the vertical stack of stressed and spaced apart semiconductor channel material nanosheets. The semiconductor device illustrated in FIG. 10 even further includes inner semiconductor spacer 20S located adjacent to the recessed inner dielectric spacer 16S. The inner semiconductor spacer 20S has an outermost sidewall that is vertically aligned to an end of each semiconductor channel material nanosheet 14 of the vertical stack of stressed and spaced apart semiconductor channel material nanosheets. In the illustrated embodiment, the strained source/drain region 18 is in compression in a longitudinal direction of current flow.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a p-type field effect transistor comprising a vertical stack of stressed and spaced apart semiconductor channel material nanosheets, a gate structure wrapped around a portion of each semiconductor channel material nanosheet of the vertical stack of stressed and spaced apart semiconductor channel material nanosheets, and a strained source/drain region located on each side of the vertical stack of stressed and spaced apart semiconductor channel material nanosheets; and
a recessed inner dielectric spacer located beneath each semiconductor channel material nanosheet of the vertical stack of stressed and spaced apart semiconductor channel material nanosheets, wherein the recessed inner dielectric spacer has an outermost sidewall that is located between a width of each semiconductor channel material nanosheet of the vertical stack of stressed and spaced apart semiconductor channel material nanosheets.

2. The semiconductor device of claim 1, wherein the strained source/drain region is in compression in a longitudinal direction of current flow.

3. The semiconductor device of claim 1, wherein the strained source/drain region is present in in an underhanging region beneath each semiconductor channel material nanosheet of the vertical stack of stressed and spaced apart semiconductor channel material nanosheets and is in direct physical contact with the outermost sidewall of the recessed inner dielectric spacer.

4. The semiconductor device of claim 1, wherein each semiconductor channel material nanosheet of the vertical stack of stressed and spaced apart semiconductor channel material nanosheets is composed of silicon, and the strained source/drain region is composed of SiGe.

5. The semiconductor device of claim 1, wherein each semiconductor channel material nanosheet of the vertical stack of stressed and spaced apart semiconductor channel material nanosheets has a stress from about 1.5 GPa to about 2.0 GPa.

6. The semiconductor device of claim 5, wherein the stress on each semiconductor channel material nanosheet of the vertical stack of stressed and spaced apart semiconductor channel material nanosheets increases with a decrease in width of the recessed inner dielectric spacer.

7. A semiconductor device comprising:
a p-type field effect transistor comprising a vertical stack of stressed and spaced apart semiconductor channel material nanosheets, a gate structure wrapped around a portion of each semiconductor channel material nanosheet of the vertical stack of stressed and spaced apart semiconductor channel material nanosheets, and a strained source/drain region located on each side of the vertical stack of stressed and spaced apart semiconductor channel material nanosheets;
a recessed inner dielectric spacer located beneath each semiconductor channel material nanosheet of the vertical stack of stressed and spaced apart semiconductor channel material nanosheets, wherein the recessed inner dielectric spacer has an outermost sidewall that is located between a width of each semiconductor channel material nanosheet of the vertical stack of stressed and spaced apart semiconductor channel material nanosheets; and
a semiconductor spacer separating the strained source/drain region from each semiconductor channel material nanosheet of the vertical stack of stressed and spaced apart semiconductor channel material nanosheets and from the recessed inner dielectric spacer.

8. The semiconductor device of claim 7, wherein the semiconductor spacer is composed of a compositionally same semiconductor material as each semiconductor channel material nanosheet of the vertical stack of stressed and spaced apart semiconductor channel material nanosheets.

9. The semiconductor device of claim 7, wherein the semiconductor spacer is in direct physically contact with an end of each semiconductor channel material nanosheet of the vertical stack of stressed and spaced apart semiconductor channel material nanosheets and in direct physical contact with the outermost sidewall of the recessed inner dielectric spacer.

10. The semiconductor device of claim 7, wherein the strained source/drain region is in compression in a longitudinal direction of current flow.

11. The semiconductor device of claim 7, wherein each semiconductor channel material nanosheet of the vertical stack of stressed and spaced apart semiconductor channel material nanosheets is composed of silicon, and the strained source/drain region is composed of SiGe.

12. The semiconductor device of claim 11, wherein each semiconductor channel material nanosheet of the vertical stack of stressed and spaced apart semiconductor channel material nanosheets has a stress from about 1.5 GPa to about 2.0 GPa.

13. The semiconductor device of claim 12, wherein the stress on each semiconductor channel material nanosheet of the vertical stack of stressed and spaced apart semiconductor channel material nanosheets increases with a decrease in width of the recessed inner dielectric spacer.

14. A semiconductor device comprising:
a p-type field effect transistor comprising a vertical stack of stressed and spaced apart semiconductor channel material nanosheets, a gate structure wrapped around a portion of each semiconductor channel material nanosheet of the vertical stack of stressed and spaced apart semiconductor channel material nanosheets, and a strained source/drain region located on each side of the vertical stack of stressed and spaced apart semiconductor channel material nanosheets;
a recessed inner dielectric spacer located beneath each semiconductor channel material nanosheet of the vertical stack of stressed and spaced apart semiconductor channel material nanosheets, wherein the recessed inner dielectric spacer has an outermost sidewall that is located between a width of each semiconductor channel material nanosheet of the vertical stack of stressed and spaced apart semiconductor channel material nanosheets; and
an inner semiconductor spacer located adjacent to the recessed inner dielectric spacer, wherein the inner semiconductor spacer has an outermost sidewall that is vertically aligned to an end of each semiconductor channel material nanosheet of the vertical stack of stressed and spaced apart semiconductor channel material nanosheets.

15. The semiconductor device of claim 14, wherein the inner semiconductor spacer is composed of a compositionally same semiconductor material as each semiconductor channel material nanosheet of the vertical stack of stressed and spaced apart semiconductor channel material nanosheets.

16. The semiconductor device of claim 14, wherein the inner semiconductor spacer separates the strained source/drain region from the recessed inner dielectric spacer.

17. The semiconductor device of claim 14, wherein the strained source/drain region is in compression in a longitudinal direction of current flow.

18. The semiconductor device of claim 14, wherein each semiconductor channel material nanosheet of the vertical stack of stressed and spaced apart semiconductor channel material nanosheets is composed of silicon, and the strained source/drain region is composed of SiGe.

19. The semiconductor device of claim 14, wherein each semiconductor channel material nanosheet of the vertical stack of stressed and spaced apart semiconductor channel material nanosheets has a stress from about 1.5 GPa to 2.0 GPa.

20. The semiconductor device of claim 19, wherein the stress on each semiconductor channel material nanosheet of the vertical stack of stressed and spaced apart semiconductor channel material nanosheets increases with a decrease in width of the recessed inner dielectric spacer.
